(19) United States
(12) Patent Application Publication
(10) Pub. No.: US 2012/0260987 A1
(43) Pub. Date: Oct. 18, 2012

(54) SOLAR CELL MODULE

(75) Inventors: Sun Jin Yun, Daejeon (KR); Soo Young Oh, Daejeon (KR); Moo Jung Chu, Daejeon (KR)

(73) Assignee: ELECTRONICS AND TELECOMMUNICATIONS RESEARCH INSTITUTE, Daejeon (KR)

(21) Appl. No.: 13/517,291

(22) PCT Filed: Jan. 20, 2011
(86) PCT No.: PCT/KR2011/000399

§ 371 Date: Jun. 20, 2012

(30) Foreign Application Priority Data
Jan. 20, 2010 (KR) 10-2010-0005324
Dec. 17, 2010 (KR) 10-2010-0130070

(51) Int. Cl. H01L 31/0203

(52) U.S. Cl. 136/259

(57) ABSTRACT

Provided is a solar cell module. The solar cell module includes a solar cell, a sealing layer configured to protect the solar cell, and a bonding layer disposed between the solar cell and the sealing layer. The bonding layer has adhesion to fix the sealing layer to the solar cell. When the sealing layer is repaired, the adhesion of the bonding layer is reduced by an external stimulation.

### TECHNICAL FIELD

The present invention disclosed herein relates to a solar cell module, and more particularly, to a solar cell module that can be easily separated and collected according to elements.

### BACKGROUND ART

Solar cells absorb light including solar light to convert light energy into electric energy. Generally, solar cells can be classified into thin film solar cells and bulk solar cells according to elements of the solar cells. In addition, according to materials used to form light absorption layers, solar cells can be classified into Si or SiGe solar cells, copper-indium-gallium-selenium (CIGS) or CdTe-based compound solar cells, group III-V compound solar cells, dye-sensitized solar cells, organic solar cells. A bulk solar cell may include an opaque back electrode, a light adsorption layer, a transparent electrode layer transmitting light and functioning as an electrode, and a metal grid layer. A semiconductor layer having a conductive type different from that of the light adsorption layer may be disposed between the light adsorption layer and the back electrode. The bulk solar cell may be packaged, for example, by using glass or a capping layer. A thin film solar cell has a structure similar to that of the bulk solar cell. Examples of thin film solar cell structures include a substrate structure using an opaque substrate, and a superstrate structure using a transparent substrate to receive light through the transparent substrate.

### DISCLOSURE

### Technical Problem

The present invention provides a solar cell module that can be easily separated and collected according to elements.

### Technical Solution

Embodiments of the present invention provide solar cell modules including: a solar cell; a sealing layer configured to protect the solar cell; and a bonding layer disposed between the solar cell and the sealing layer and having adhesion to fix the sealing layer to the solar cell, wherein when the sealing layer is repaired, the adhesion of the bonding layer is reduced by an external stimulation.

In some embodiments, the external stimulation may be ultraviolet irradiation, and the bonding layer may include a photodegradable polymer. The photodegradable polymer may include at least one selected from the group consisting of ethylene-carbon monoxide copolymers, vinyl ketone-based copolymers, thermoplastic 1,2-polybutadiene, polyisobutylene, polymers with triplet photosensitizer, and polymers with metal compound.

In other embodiments, the external stimulation may be a temperature variation, and the bonding layer may include a mixture of a thermoplastic resin and a plasticizer. The thermoplastic resin may include at least one of ethylene vinylacetate (EVA), ethylene acrylate, polyolefin, or polyethylene.

The plasticizer may include at least one of terpene phenol resin, glyceryl tribenzoate, or pentaerythritol tetrabenzoate. If the bonding layer is heated or cooled to a temperature out of an adhesion temperature range, the adhesion of the bonding layer may not be maintained.

In still other embodiments, the external stimulation may be a temperature variation, and the sealing layer and the bonding layer may have different thermal expansion coefficients.

In even other embodiments, the external stimulation may be application of a mechanical force. In this case, the bonding layer may include: 100 parts by weight of polymer derived from a monomer mixture; 20 to 400 parts by weight of plasticizer having a boiling point of 150° C. or higher; and 10 to 1,000 parts by weight of thermally conductive filler, wherein the monomer mixture may include: 70 to 100 parts by weight of at least one alkyl(meth)acrylate having an alkyl group containing from 2 to 14 carbon atoms on average; and 0 to 30 parts by weight of at least one monoethylene-based monomer capable of reacting with the alkyl(meth)acrylate to form a copolymer.

In yet other embodiments, the external stimulation may be one of ultraviolet irradiation, a temperature variation, dissolution in an organic solvent, application of a mechanical force, and a combination thereof.

### Advantageous Effects

According to the embodiments of the present invention, the bonding layers of the solar cell module have adhesion to fix the sealing layers to the solar cell, and the adhesion of the bonding layers can be reduced by an external stimulation when the sealing layers are repaired. Therefore, the solar cell module can be easily separated and collected according to the elements of the solar cell module. In addition, according to the embodiments of the present invention, since the elements of the solar cell module can be collected and recycled, costs can be reduced, and environmental pollution can be reduced because the elements can be separately discarded.

### DESCRIPTION OF DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a sectional view illustrating a solar cell module according to an embodiment of the present invention;

FIGS. 2A through 2D are sectional views for explaining a method of fabricating a solar cell module according to an embodiment of the present invention;

FIGS. 3A and 3B are sectional views for explaining a method of separating and collecting elements of a solar cell module by irradiating ultraviolet light according to an embodiment of the present invention;

FIGS. 4A and 4B are sectional views for explaining a method of separating and collecting elements of a solar cell module by varying temperature according to an embodiment of the present invention;

FIGS. 5A and 5B are sectional views for explaining a method of separating and collecting elements of a solar cell module by dissolving the solar cell module in an organic solvent according to an embodiment of the present invention; and

FIGS. 6A and 6B are sectional views for explaining a method of separating and collecting elements of a solar cell module by applying a mechanical force to the solar cell module according to an embodiment of the present invention.

### MODE FOR INVENTION

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the dimensions of elements are exaggerated for clarity of illustration, like reference numerals refer to like elements.

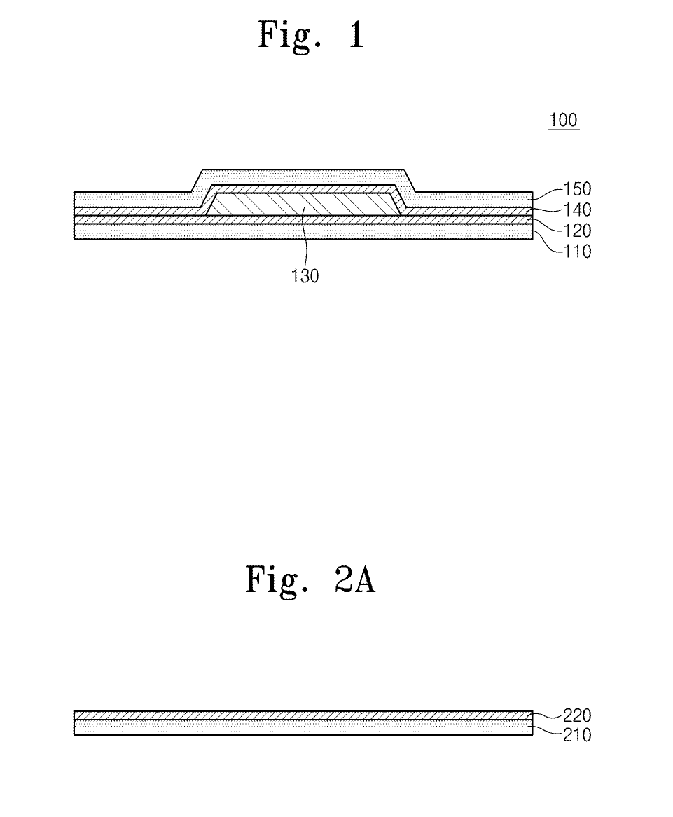

FIG. 1 is a sectional view illustrating a solar cell module 100 according to an embodiment of the present invention.

Referring to FIG. 1, the solar cell module of the current embodiment may include: a lower bonding layer 120 disposed on a lower sealing layer 110, a solar cell 130 disposed at a portion region on the lower bonding layer 120; an upper bonding layer 140 disposed on the solar cell 130 and the lower bonding layer 120; and an upper sealing layer 150 disposed on the upper bonding layer 140 at a side opposite to the lower sealing layer 110.

The lower and upper sealing layers 110 and 150 may be formed of an organic material. The lower sealing layer 110 is disposed at a back electrode side of the solar cell 130, and the upper sealing layer 150 is disposed at a light-receiving surface side of a front electrode of the solar cell 130.

The lower and upper bonding layers 120 and 140 have adhesion so that the lower and upper sealing layers 110 and 150 can be fixed to the solar cell 130. When the lower and upper sealing layers 110 and 150 are repaired, the adhesion of the lower and upper bonding layers 120 and 140 may be reduced by an external stimulation such as ultraviolet irradiation, temperature variation caused by heating or cooling, dissolution in organic solvent, application of a mechanical force, and a combination thereof.

In detail, if the external stimulation is ultraviolet irradiation, the lower and upper bonding layers 120 and 140 may include a photodegradable polymer. For example, the lower and upper bonding layers 120 and 140 may include at least one photodegradable polymer selected from the group consisting of ethylene-carbon monoxide copolymers, vinyl ketone-based copolymers, thermoplastic 1,2-polybutadiene, polyisobutylene, polyisobutylene oxide, polymers with triplet photosensitizer, and polymers with metal compound.

If the external stimulation is temperature variation, the lower and upper bonding layers 120 and 140 may be formed by adding plasticizer to a thermoplastic resin. For example, the thermoplastic resin may be one of ethylene vinylacetate (EVA), ethylene acrylate, polyolefin, and polyethylene. For example, the plasticizer may be one of terpene phenol resin, glyceryl tribenzoate, and pentaerythritol tetrabenzoate. The melting point of the thermoplastic resin is varied according to the amount of the plasticizer added to the thermoplastic resin.

If the external stimulation is application of a mechanical force, the lower and upper bonding layers 120 and 140 may be formed of a pressure sensitive adhesive. For example, the pressure sensitive adhesive may include: 100 parts by weight of polymer derived from a monomer mixture; 20 to 400 parts by weight of plasticizer having a boiling point of 150° C. or higher; and 10 to 1,000 parts by weight of thermally conductive filler. The monomer mixture may include: 70 to 100 parts by weight of at least one alkyl(meth)acrylate wherein the alkyl group contains from 2 to 14 carbon atoms on average; and 0 to 30 parts by weight of at least one monoethylene-based monomer that can react with the alkyl(meth)acrylate to form a copolymer.

The thermal expansion coefficient of the lower and upper bonding layers 120 and 140 may be different from that of the lower and upper sealing layers 110 and 150.

The lower and upper bonding layers 120 and 140 may be easily separated from the solar cell 130 without residues on the solar cell 130, for example, by ultraviolet irradiation, temperature variation, dissolution in organic solvent, application of a mechanical force, and a combination thereof.

For example, the solar cell 130 may be a Si or SiGe solar cell, a copper-indium-gallium-selenium (CIGS) or CdTe-based compound solar cell, a group III-V compound solar cell, a dye-sensitized solar cell, or an organic solar cell.

The solar cell 130 may include a glass substrate or a flexible substrate.

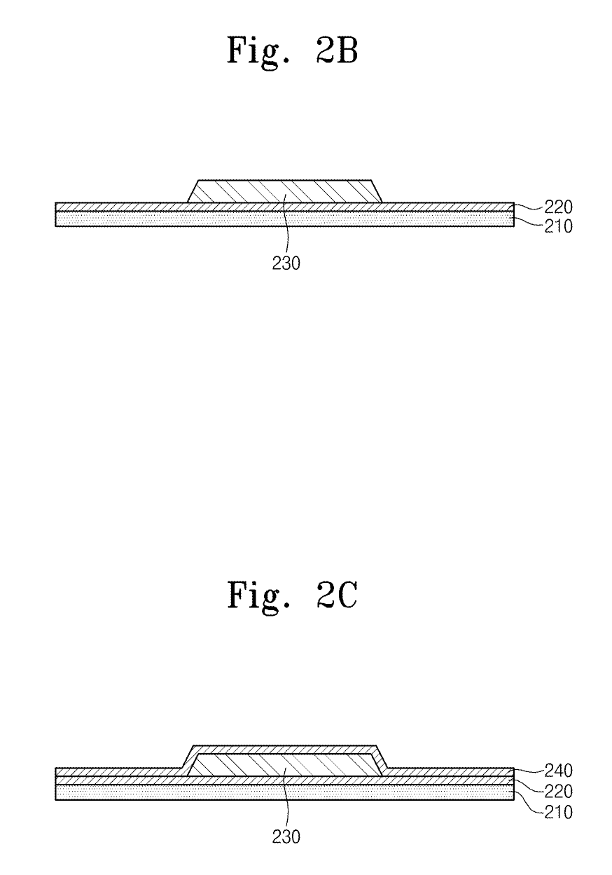

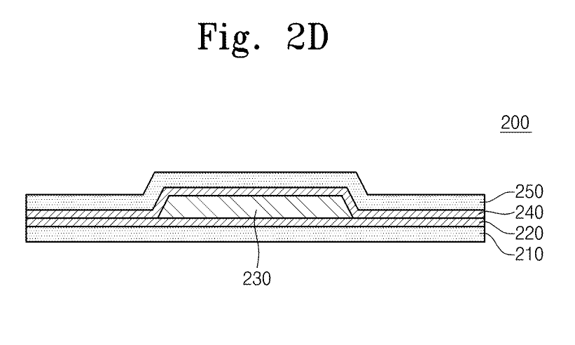

FIGS. 2A through 2D are sectional views for explaining a method of fabricating a solar cell module according to an embodiment of the present invention. Hereinafter, with reference to FIGS. 2A through 2D, a brief explanation will be given of a method of fabricating a solar cell module according to an embodiment of the present invention.

Referring to FIG. 2A, a lower sealing layer 210 is prepared, and a lower bonding layer 220 is disposed on the lower sealing layer 210.

The lower sealing layer 210 is provided to protect a solar cell from external environments such as moisture permeation into a back electrode side of the solar cell. For example, the lower sealing layer 210 may be formed of an organic material such as a polyolefin-based resin, a urethane resin, and a silicon resin. Examples of the polyolefin-based resin include ethylene vinylacetate copolymer (EVA), ethylene acrylic acid methyl copolymer (EMA), ethylene acrylic acid ethyl copolymer (EEA), and butyral resin.

The lower bonding layer 220 may be formed of an organic material. For example, the lower bonding layer 220 may include a photodegradable polymer. For example, the photodegradable polymer may be at least one selected from the group consisting of ethylene-carbon monoxide copolymers, vinyl ketone-based copolymers, thermoplastic 1,2-polybutadiene, polyisobutylene, polyisobutylene oxide, polymers with triplet photosensitizer, and polymers with metal compound.

Alternatively, the lower bonding layer 220 may be formed by adding plasticizer to a thermoplastic resin. For example, the thermoplastic resin may be one of ethylene vinylacetate (EVA), ethylene acrylate, polyolefin, and polyethylene. For example, the plasticizer may be one of terpene phenol resin, glyceryl tribenzoate, and pentaerythritol tetrabenzoate. The melting point of the thermoplastic resin may be varied according to the amount of the plasticizer added to the thermoplastic resin.

For example, the lower bonding layer 220 may include a pressure sensitive adhesive. For example, the pressure sensitive adhesive may include: 100 parts by weight of polymer derived from a monomer mixture; 20 to 400 parts by weight of plasticizer having a boiling point of 150° C. or higher; and 10 to 1,000 parts by weight of thermally conductive filler. Based on the total weight of the monomer mixture, the monomer mixture may include: 70 to 100 parts by weight of at least one alkyl(meth)acrylate wherein the alkyl group contains from 2 to 14 carbon atoms on average; and 0 to 30 parts by weight of at least one monoethylene-based monomer that can react with the alkyl(meth)acrylate to form a copolymer.

The lower bonding layer 220 has adhesion so that the lower sealing layer 210 can be fixed to a solar cell (refer to reference numeral 230 in FIG. 2D) that will be disposed on the lower bonding layer 220. The adhesion of the lower bonding layer 220 may be reduced by an external stimulation such as ultraviolet irradiation, temperature variation caused by heating or cooling, dissolution in organic solvent, application of a mechanical force, and a combination thereof. In this case, when the lower sealing layer 210 is repaired, the lower sealing layer 210 may be easily detached from the solar cell. This is possible because the material used to form the lower bonding layer 220 have the following characteristics. If ultraviolet light is irradiated on the photodegradable polymer, the ring of the photodegradable polymer is broken, and thus the physical characteristics such as adhesion of the photodegradable polymer are degraded. In the case of a mixture of thermoplastic resin and plasticizer, the adhesion of the mixture is maintained in a certain temperature range. However, if the mixture is heated higher than the temperature range, the mixture may melt and the adhesion of the mixture may disappear, or if the mixture is cooled lower than the certain temperature, the flexibility of the mixture may decrease and the adhesion of the mixture may disappear. If the solar cell is used for a long time, the bonding strength between the solar cell and the lower sealing layer 210 becomes weak because the adhesion of the pressure sensitive adhesive reduces.

In addition, the lower bonding layer 220 may be formed of a material having a thermal expansion coefficient different from that of a material used to form the lower sealing layer 210. In this case, if temperature varies, the lower bonding layer 220 may be stripped by a deformation force caused by different thermal expansion coefficients of materials.

Referring to FIG. 2B, a solar cell 230 is disposed at a portion region on the lower bonding layer 220.

The solar cell 230 may be a Si or SiGe solar cell, a CIGS or CdTe-based compound solar cell, a group III-V compound solar cell, a dye-sensitized solar cell, or an organic solar cell. However, the solar cell 230 is not limited thereto.

The solar cell 230 is fixed on the lower bonding layer 220 owing to the adhesion of the lower bonding layer 220.

Referring to FIG. 2C, an upper bonding layer 240 is disposed on the solar cell 230 and the exposed part of the lower bonding layer 220.

The upper bonding layer 240 may be formed of the same organic material used to form the lower bonding layer 220. In this case, the upper bonding layer 240 has adhesion so that the solar cell 230 can be fixed to an upper sealing layer (refer to reference numeral 250 in FIG. 2D) that will be formed later. The adhesion of the upper bonding layer 240 may be reduced by an external stimulation such as ultraviolet irradiation, temperature variation caused by heating or cooling, dissolution in organic solvent, application of a mechanical force, and a combination thereof. Thus, when the upper sealing layer (refer to reference numeral 250 in FIG. 2D) is repaired, the upper sealing layer may be easily detached from the solar cell 230.

In addition, the upper bonding layer 240 may be formed of a material having a thermal expansion coefficient different from that of a material used to form the upper sealing layer. In this case, if temperature varies, the upper bonding layer 240 may be stripped by a deformation force caused by different thermal expansion coefficients of materials.

Referring to FIG. 2D, an upper sealing layer 250 is disposed on the upper bonding layer 240 to protect the solar cell 230 mechanically and chemically.

Since the upper sealing layer 250 is disposed on a light-receiving surface side of a front electrode of the solar cell 230, the upper sealing layer 250 is formed of a material having good transparency and capable of maintaining its transparency for a long time. For example, the upper sealing layer 250 may be formed of an organic material such as a polyolefin resin, a urethane resin, and a silicon resin. Examples of the polyolefin resin may be include EVA, EMA, EEA, and butyral resin.

In this way, a solar cell module 200 can be fabricated, which includes the lower and upper sealing layers 210 and 250, the solar cell 230, and the lower and upper bonding layers 220 and 240 disposed therebetween.

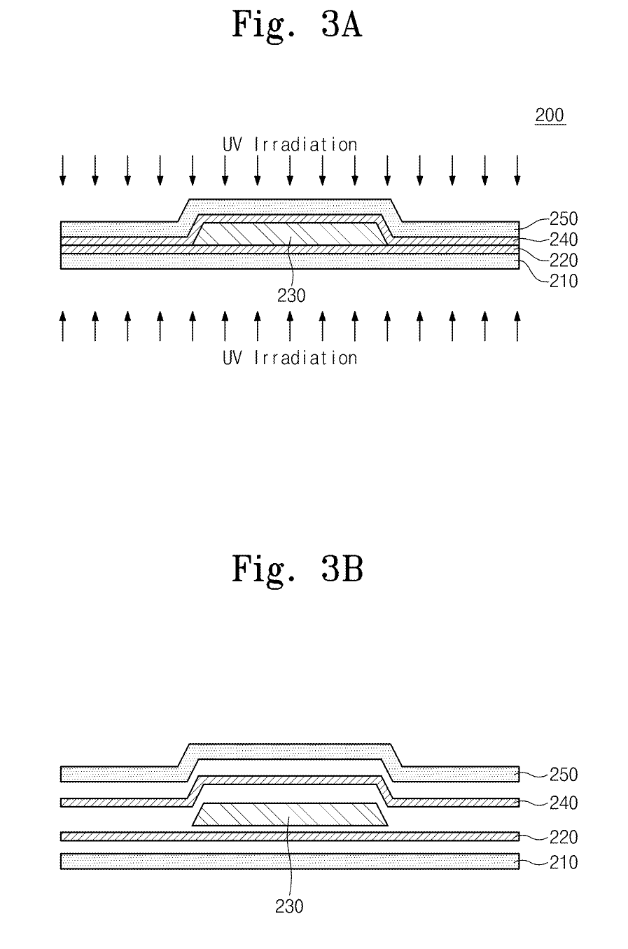

FIGS. 3A and 3B are sectional views for explaining a method of separating and collecting elements of a solar cell module by irradiating ultraviolet light according to an embodiment of the present invention.

Referring to FIG. 3A, the solar cell module 200 fabricated according to the embodiment of the present invention is prepared, and to repair the lower and upper sealing layers 210 and 250, ultraviolet light is irradiated toward the lower and upper bonding layers 220 and 240 from both side of the solar cell 230. The lower and upper bonding layers 220 and 240 may include a photodegradable polymer. The photodegradable polymer may be at least one selected from the group consisting of ethylene-carbon monoxide copolymers, vinyl ketone-based copolymers, thermoplastic 1,2-polybutadiene, polyisobutylene, polyisobutylene oxide, polymers with triplet photosensitizer, and polymers with metal compound.

Referring to FIG. 3B, the polymer rings of the lower and upper bonding layers 220 and 240 are broken due to the ultraviolet irradiation, and thus the physical characteristics such as adhesion of the lower and upper bonding layers 220 and 240 are degraded. Therefore, the lower and upper sealing layers 210 and 250 can be easily separated from the solar cell 230. That is, the solar cell 230 can be easily collected from the solar cell module 200 (refer to FIG. 3A) without damage, and the lower and upper sealing layers 210 and 250 can be separately collected and discarded.

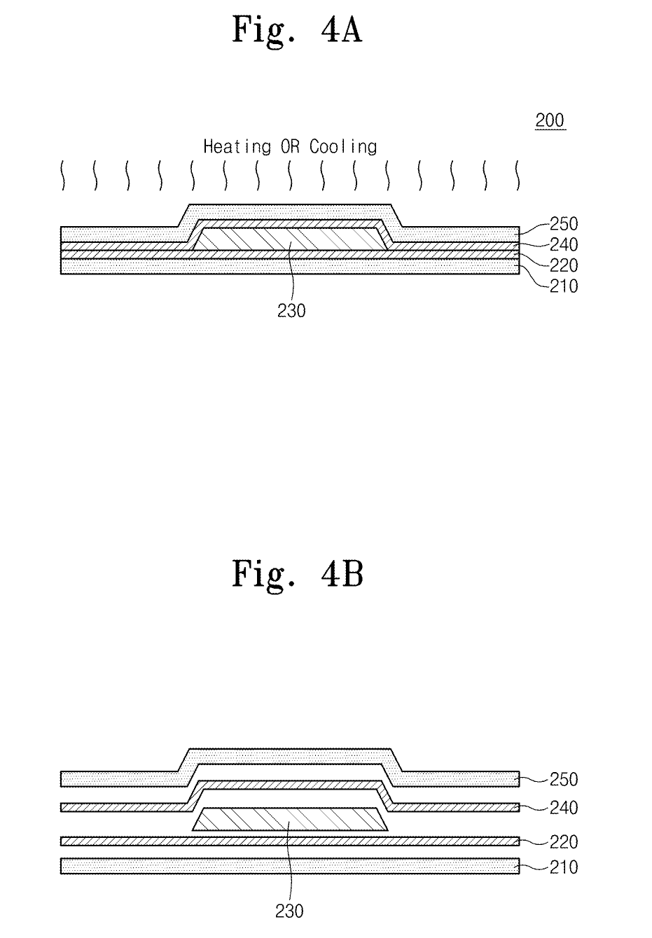

FIGS. 4A and 4B are sectional views for explaining a method of separating and collecting elements of a solar cell module by varying temperature according to an embodiment of the present invention.

Referring to FIG. 4A, the solar cell module 200 fabricated according to the embodiment of the present invention is prepared, and to repair the lower and upper sealing layers 210 and 250 disposed under and above the solar cell 230, the temperature of the lower and upper bonding layers 220 and 240 are varied by heating or cooling them. The lower and upper bonding layers 220 and 240 may include a mixture of thermoplastic resin and plasticizer. The thermoplastic resin may be one of ethylene vinylacetate (EVA), ethylene acrylate, polyolefin, or polyethylene. The plasticizer may be one of terpene phenol resin, glyceryl tribenzoate, or pentaerythritol tetrabenzoate.

Referring to FIG. 4B, generally, the lower and upper bonding layers 220 and 240 can maintain their adhesion in a certain temperature range. However, if the lower and upper bonding layers 220 and 240 are heated higher than the temperature range, the lower and upper bonding layers 220 and 240 melt and lost their adhesion, or if the lower and upper bonding layers 220 and 240 are cooled lower than the certain temperature, the lower and upper bonding layers 220 and 240 decrease in flexibility and lost their adhesion. Therefore, the lower and upper sealing layers 210 and 250 can be easily separated from the solar cell 230. At this time, the heating temperature of the lower and upper bonding layers 220 and 240 may be kept equal to or lower than 250° C. to prevent the solar cell 230 from being damaged by a thermal attack.

If the lower and upper bonding layers 220 and 240 are formed of a material having a thermal expansion coefficient different from that of a material used to form the lower and upper sealing layers 210 and 250, the temperature of the solar cell module 200 may be varied by heating or cooling to strip the lower and upper bonding layers 220 and 240 from the lower and upper sealing layers 210 and 250 and the solar cell 230 by using a deformation force caused by different thermal expansion coefficients. That is, the lower and upper sealing layers 210 and 250 can be easily separated from the solar cell 230.

In this way, the solar cell 230 can be easily collected from the solar cell module 200 (refer to FIG. 4A) without damage, and the lower and upper sealing layers 210 and 250 can be separately collected and discarded.

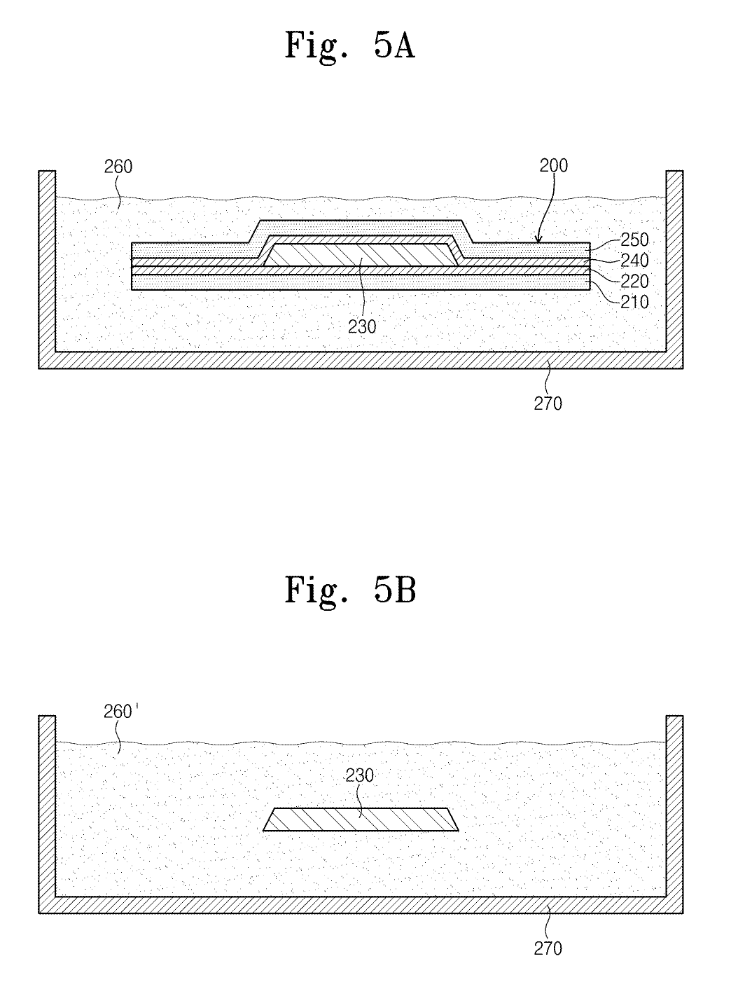

FIGS. 5A and 5B are sectional views for explaining a method of separating and collecting elements of a solar cell module by dissolving the solar cell module in an organic solvent according to an embodiment of the present invention.

Referring to FIG. 5A, the solar cell module 200 fabricated according to the embodiment of the present invention is prepared, and to repair the lower and upper sealing layers 210 and 250 disposed under and above the solar cell 230, the solar cell module 200 is immersed into a chamber 270 containing an organic solvent 260. The lower and upper sealing layers 210 and 250 and the lower and upper bonding layers 220 and 240 may be formed of organic materials.

Referring to FIG. 5B, the lower and upper sealing layers 210 and 250 (refer to FIG. 5A) immersed in the organic solvent 260 (refer to FIG. 5A) are dissolved, and the lower and upper bonding layers 220 and 240 (refer to FIG. 5A) immersed in the organic solvent 260 (refer to FIG. 5A) are dissolved. As a result, only the solar cell 230 remains in the chamber 270 containing the organic solvent 260′ in which organic materials are dissolved. That is, the solar cell 230 can be easily separated from the lower and upper sealing layers 210 and 250 (refer to FIG. 5A) of the solar cell module 200 (refer to FIG. 5A) without damage.

Thereafter, the solar cell 230 may be taken out of the chamber 270 and be washed and dried (not shown).

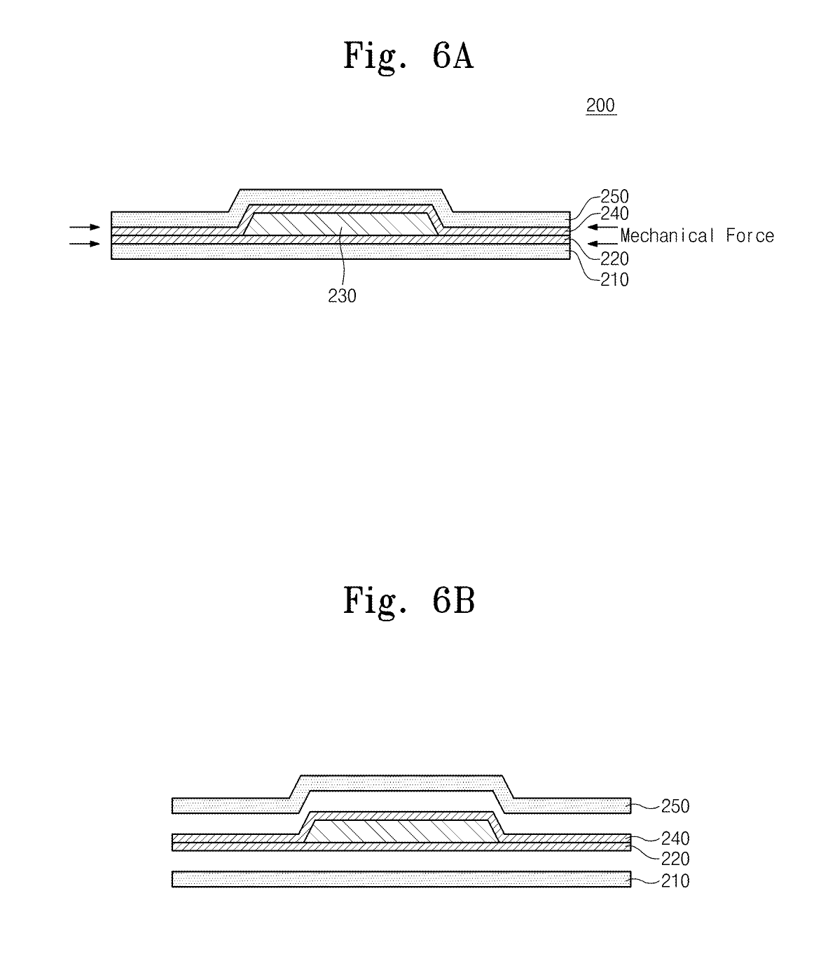

FIGS. 6A and 6B are sectional views for explaining a method of separating and collecting elements of a solar cell module by applying a mechanical force to the solar cell module according to an embodiment of the present invention.

Referring to FIG. 6A, the solar cell module 200 fabricated according to the embodiment of the present invention is prepared, and to repair the lower and upper sealing layers 210 and 250 disposed under and above the solar cell 230, a mechanical force is applied to the lower and upper bonding layers 220 and 240. The lower and upper bonding layers 220 and 240 may include a pressure sensitive adhesive. For example, the pressure sensitive adhesive may include: 100 parts by weight of polymer derived from a monomer mixture; 20 to 400 parts by weight of plasticizer having a boiling point of 150° C. or higher; and 10 to 1,000 parts by weight of thermally conductive filler. Based on the total weight of the monomer mixture, the monomer mixture may include: 70 to 100 parts by weight of at least one alkyl(meth)acrylate wherein the alkyl group contains from 2 to 14 carbon atoms on average; and 0 to 30 parts by weight of at least one monoethylene-based monomer that can react with the alkyl(meth)acrylate to form a copolymer.

Referring to FIG. 6B, in the case where the lower and upper bonding layers 220 and 240 are formed of the pressure sensitive adhesive, as the solar cell 230 is used for a long time, the bonding strength between the solar cell 230 and the lower and upper sealing layers 210 and 250 becomes weak because the adhesion of the pressure sensitive adhesive reduces. In this case, if a mechanical force is applied to the lower and upper bonding layers 220 and 240, the lower and upper bonding layers 220 and 240 are easily separated from the lower and upper sealing layers 210 and 250. Therefore, the lower and upper sealing layers 210 and 250 can be easily separated from the solar cell 230 of the solar cell module 200 (refer to FIG. 6A) without damaging the solar cell 230.

In this way, the solar cell 230 can be easily collected from the solar cell module 200 (refer to FIG. 6A) without damage by applying a mechanical force, and the lower and upper sealing layers 210 and 250 can be separately collected and discarded.

According to the embodiments of the present invention, the adhesion of the bonding layers of the solar cell module can be reduced by an external stimulation such as ultraviolet irradiation, temperature variation caused by heating or cooling, dissolution in organic solvent, and application of a mechanical force, so as to separate the sealing layers and the solar cell from the solar cell module without damaging the solar cell. As a result, before the characteristics of the solar cell decrease below a certain level due to degradation or damage of the sealing layers, the solar cell can be collected and re-sealed for recycling. Thus, the lifetime of the solar cell module can be easily increased. At this time, since partially damaged parts can be replaced or repaired, manufacturing and discarding costs can be reduced, and waste of resources can be reduced. In addition, since elements of the solar cell module can be separately discarded, environmental pollution can be reduced.

In the above embodiments of the present invention, the sealing layers and the solar cell are separated from the solar cell module by an external stimulation such as ultraviolet irradiation, temperature variation caused by heating or cooling, dissolution in organic solvent, and application of a mechanical force. However, the present invention is not limited thereto. For example, the sealing layers and the solar cell may be separated from the solar cell module by combining at least two of the above-mentioned stimulations. Examples of combinations of such external stimulations includes a combination of temperature variation and application of a mechanical force, a combination of ultraviolet irradiation and application of a mechanical force, and a combination of ultraviolet irradiation, temperature variation, and application of a mechanical force.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A solar cell module comprising:
a solar cell;
a sealing layer configured to protect the solar cell; and
a bonding layer disposed between the solar cell and the sealing layer and having adhesion to fix the sealing layer to the solar cell,
wherein when the sealing layer is repaired, the adhesion of the bonding layer is reduced by an external stimulation.

2. The solar cell module of claim 1, wherein the external stimulation is ultraviolet irradiation.

3. The solar cell module of claim 2, wherein the bonding layer comprises a photodegradable polymer.

4. The solar cell module of claim 3, wherein the photodegradable polymer comprises at least one selected from the group consisting of ethylene-carbon monoxide copolymers, vinyl ketone-based copolymers, thermoplastic 1,2-polybutadiene, polyisobutylene, polymers with triplet photosensitizer, and polymers with metal compound.

5. The solar cell module of claim 1, wherein the external stimulation is a temperature variation.

6. The solar cell module of claim 5, wherein if the bonding layer is heated or cooled to a temperature out of an adhesion temperature range, the adhesion of the bonding layer is not maintained.

7. The solar cell module of claim 6, wherein the bonding layer comprises a mixture of a thermoplastic resin and a plasticizer.

8. The solar cell module of claim 7, wherein the thermoplastic resin comprises at least one of ethylene vinylacetate (EVA), ethylene acrylate, polyolefin, or polyethylene, and the plasticizer comprises at least one of terpene phenol resin, glyceryl tribenzoate, or pentaerythritol tetrabenzoate.

9. The solar cell module of claim 5, wherein the sealing layer and the bonding layer have different thermal expansion coefficients.

10. The solar cell module of claim 1, wherein the external stimulation is application of a mechanical force.

11. The solar cell module of claim 10, wherein the bonding layer comprises:
100 parts by weight of polymer derived from a monomer mixture;
20 to 400 parts by weight of plasticizer having a boiling point of 150° C. or higher; and
10 to 1,000 parts by weight of thermally conductive filler, wherein the monomer mixture may comprises:
70 to 100 parts by weight of at least one alkyl(meth)acrylate having an alkyl group containing from 2 to 14 carbon atoms on average; and
0 to 30 parts by weight of at least one monoethylene-based monomer capable of reacting with the alkyl(meth)acrylate to form a copolymer.

12. The solar cell module of claim 1, wherein the external stimulation is one of ultraviolet irradiation, a temperature variation, dissolution in an organic solvent, application of a mechanical force, or a combination thereof.
